(19) United States
(12) Patent Application Publication
(10) Pub. No.: US 2016/0099548 A1
(43) Pub. Date: Apr. 7, 2016

(54) External cavity with a pair of two Fiber Bragg gratings at the front and back facet of a laser diode

(71) Applicants: Pin Long, LASALLE (CA); Nikolay Naydenov, LASALLE (CA)

(72) Inventors: Pin Long, LASALLE (CA); Nikolay Naydenov, LASALLE (CA)

(21) Appl. No.: 14/503,909

(22) Filed: Oct. 1, 2014

(51) Int. Cl. H01S 5/14; H01S 5/068; H01S 5/028; G02B 6/02

(52) U.S. Cl. CPC H01S 5/141; H01S 5/147; G02B 6/02076; H01S 5/068; H01S 5/0287

(57) ABSTRACT

A semiconductor laser chip is placed in between two Fiber Bragg gratings (FBGs), which are used as external cavities for the laser, to stabilize its center wavelength and to reduce its bandwidth.

The first FBG is placed at the front facet of the laser chip, while the second FBG is placed on the back facet of the chip. The two FBGs are used to form an external cavity. Both FBGs can have same central wavelengths, different reflectivities and different bandwidths. The distance between the laser chip and the FBGs can varies from few millimeters to several meters. Since the FBGs have a very small wavelength drift with temperature fluctuations, the semiconductor laser has a stable center wavelength output. Another benefit of this setup is that the bandwidth of laser diode is also reduced.

In this newly proposed technology, an External cavity laser diode (ECL) is an optical system configuration, in which an optical feedback is provided by a pair of two Fiber Bragg Gratings (FBGs) to control the LD output characteristics. It consists of a semiconductor laser diode, two optical fibers with two different reflectivity FBGs, into which the light is coupled.

This technique uses a semiconductor laser diode chip as a light source, and two Fiber Bragg Gratings (FBGs) to form laser cavities. The light emitted from both front and back facets of the chip is coupled into two separate fibers, on which the two different reflectivity FBGs are written. In such way, the bandwidth of a laser diode can be reduced significantly, and also the wavelength fluctuations are stabilized. The output is taken from the FBG fiber facing the front of the laser.

Some of the most important characteristics associated with an ECL are reduction in threshold lasing current and the bandwidth, and also high wavelength and output power stability.

### BACKGROUND OF INVENTION

Narrow bandwidth laser sources are very important for optical fiber telecommunication applications. The core technology of DWDM is to increase the capacity of fiber by using multiple wavelengths to carry the information. The center wavelength stability of laser sources is very critical for DWDM optical systems. Narrow bandwidth laser sources are very important devices for instrumentation, sensor, biomedical, metrology and telecommunication applications. Solid-state lasers have advantages in compactness and efficiency over other types. To achieve a single transverse mode laser, one can use different techniques to suppress the high order transverse modes.

Fiber Bragg gratings were first used by Rogers, Grant and Brian F. Ventrudo [1] to stabilize the intensity and frequency fluctuations of laser diodes. In their invention, an optical lens is used to couple the laser diode with optical fiber which contains the fiber Bragg grating. Later, Jean-Marc Verdiell has used fiber Bragg gratings with high reflectivity back facet laser diodes to form an external cavity for suppression of longitudinal mode hops and compensation of wavelength shift [2]. An invention by Dmitri V. Kuksenkov uses fiber gratings to define the end of the optical cavity for discriminating against the lasing of higher-order transverse modes in the multi-mode gain region [3].

Other inventors have used volume holographic gratings as external cavities to reduce laser bandwidth and to stabilize laser operation wavelength (U.S. Pat. No. 5,691,989). Volume holographic gratings are of small size (around 1 mm³) and they can be packaged inside a TO-Can of a laser diode. A laser diode with a volume holographic grating external cavity still has a free space beam. Several companies now manufacture laser diodes with volume holographic external cavities.

There are, of course, some disadvantages of using Fiber Bragg Gratings as external cavities to suppress longitude and lateral mode hops:

(1) the light from the laser diodes must be coupled into the optical fiber, where there are low coupling efficiency and significant losses;

(2) FBG is located at some distance from the fiber tip, and therefore the length of the optical cavity is longer; longer external cavities makes the modulation of the laser diode difficult at a high frequency;

(3) there are many applications that need free space laser diodes and do not need light to be coupled into an optical fiber, which limits the use of FBGs as external cavities;

(4) bigger package due to the back facet placed FBG.

Pin Long has used sliced FBG as external cavity for laser diode that overcomes the above problems and laser diode does not have to be coupled into fiber [4]. The sliced FBG can be a free space optical element in order to reduce light intensity loss due to fiber coupling. A sliced FBG can also reduce the laser diode cavity length significantly for high speed modulation. Short cavity length can also increase the stability of laser diode wavelength drift due to environment temperature change.

Up to now, the most of FBG external cavity technologies have been successfully applied to single mode laser diode for wavelength stability and bandwidth reduction. In those technologies, mostly volume gratings are used as an external cavity for multimode laser diodes.

Hong-Gang Yu and others have used a multimode fiber Bragg grating as external cavity to stabilize wavelength and reduce bandwidth of a single mode laser diode [5].

There are several reasons which make difficult the use of multimode FBG as external cavity for multimode laser diodes:

(1) since there are many modes of multimode laser diode launching into the multimode fiber, only one mode will interact with the FBG in multimode fiber; in most cases, that will be the basic mode;

(2) because the FBG on multimode fiber should be placed many centimeters away from laser facet to utilize coherent collapsing for stabilizing wavelength, the cavity length of the multimode laser diode becomes very long, which makes the center wavelength extremely difficult to be stabilized;

(3) the long FBG external cavity multimode laser diode package cannot be practically implemented.

To solve above problems, the present invention suggests the use two FBGs; one at front facet and one at back facet, as an external cavity for laser diode, especially for multimode laser diode to achieve wavelength stability and bandwidth suppression.

### OBJECTS OF THE INVENTION

An object of the present invention is to provide a new technique for significantly reducing the bandwidth of a laser diode, where two Fiber Bragg gratings are used to create an external cavity that will select only one lasing wavelength and suppress all the other lasing wavelengths coming from the laser.

Another object of the present invention is to provide increased stability of the central wavelength of the proposed external cavity laser diode.

Another object of the present invention is to provide increased stability of the output power of the proposed external cavity laser diode.

Another object of the present invention is to provide reduced bandwidth of the proposed external cavity laser diode.

Still another object of the present invention is to provide a single wavelength, stabilized and narrow bandwidth multimode laser, generated by the external cavity of two Fiber Bragg Gratings, at a low cost.

### SUMMARY OF THE INVENTION

According to the present invention, a narrow-bandwidth and wavelength stabilized laser source is created by using an external cavity made of two Fiber Bragg Gratings (FBGs). The first FBG is placed at front facet of the laser diode, and a second one—at back facet of the laser diode, to suppress laser diode bandwidth and to stabilize laser diode wavelength.

With the reference to the attached pictures and drawing, and the legend to the drawings, here is the summary of the present invention:

(1) A laser diode [1] is a single mode laser diode or multi mode laser diode.

(2) A multimode fiber [5] is coupled directly with laser diode front facet [2], and has a FBG written on it [4].

(3) A multimode fiber [7] is coupled directly with laser diode back facet [3], and has a FBG written on it [6].

(4) In one case, FBG [4] has low reflectivity and the distance from the fiber tip D1 is long (D1>10 cm); and FBG [6] has a higher reflectivity and the distance from the fiber tip D2 is short (D2<1 cm).

(5) In another case, both FBG [4] and FBG [6] are far from the laser, meaning both D1>10 cm and D2>10 cm.

(6) In another case, both FBG [4] and FBG [6] are close to the laser, meaning both D1<1 cm and D2<1 cm.

(7) In another case, the FBG [4] has high reflectivity, and the FBG [6]—low reflectivity.

(8) In another case, both FBG [4] and FBG [6] have low reflectivity.

(9) In another case, both FBG [4] and FBG [6] have high reflectivity.

(10) In another case, the bandwidth of FBG [4] is narrow, and bandwidth of FBG [6] is wide; and the center wavelengths of both FBGs are overlapping.

(11) In another case, the front facet laser diode multimode fiber is coupled using an optical lens; and the back facet laser diode multimode fiber is coupled using another optical lens (FIG. 2).

(12) In another case, a lensed fiber is used to couple the light into Fiber [5] and FBG [4], and another lensed fiber is used to the light into Fiber [7] and FBG [6] (FIG. 3).

(13) In one case, the front facet and back facet of laser diode are both coated with anti-reflection (AR) coating.

(14) In another case, the front facet is coated with anti-reflection coating (AR), and the back facet is coated with high-reflection coating (HR).

(15) In another case, the both front facet and the back facet of the laser diode are not coated.

(16) In another case, the fibers' tips facing the laser diode are terminated with flat cleave, and the other ends are terminated with angled cleave.

(17) In another case, the Fiber [5] facing the front emitting surface of the laser diode has second

FBG [12] written on it, located at distance D3, and the Fiber [7] facing the back emitting surface has a single FBG [6] (FIG. 4).

(18) In another case, the Fiber [7] facing the back emitting surface of the laser diode has second FBG [13] written on it, located at distance D4, and the Fiber [5] facing the front emitting surface has a single FBG [4] (FIG. 5).

(19) In another case, the fiber [5] has two FBGs [4] and [12], located at distance D3 and the fiber has also two FBGs [6] and [13], located at distance D4 respectively (FIG. 6).

### DETAILED DESCRIPTION OF INVENTION

With the reference to the FIG. 1 to FIG. 6, and the legend to the drawings, the present invention will be herein described for indicative purpose and by no means of limitation.

In the proposed method for making External Cavity, first a laser diode had to be chosen. The tests were performed with a high power multi-mode laser diode.

For optimal and stable operation, the laser diode was fixed on a specially designed cooling setup with TEC, heat sink and fan. Also, a thermistor feedback was used for precise monitoring of the LD temperature, and regulating the TEC current.

The laser assembly then was mounted on a special support, allowing the access both from the front and back emitting surfaces.

According to the characteristics of the laser diode, two uniform FBGs were manufactured on two different multi mode fibers. The central wavelength of both FBGs was matching the peak wavelength of the laser. The FBG [4] was manufactured with lower reflectivity (20%), and the FBG [6]—with higher reflectivity (85%). Location of the FBG [4] was at distance 1 m from one of the ends of the fiber. Location of the FBG [6] was in the middle of the fiber.

Next, the light from both front and back emitting facet of the diode was coupled into the two FBG fibers. To form an external cavity, the low-reflectivity FBG [4] was placed and coupled with the light from the higher power front facet of the LD [2], and the high reflectivity FBG [6]—with the light coming out of the back facet [3]. The fiber [5] from the front facet was taken as a main output, from which the power and spectrum was measured.

Based on our experiments and tests, the low-reflectivity FBG [4] was located at minimum distance D1=1 m from the front emitting facet along the fiber. Also, the high-reflectivity FBG [6] was located as close as possible to the back emitting facet of the diode D2<1 cm.

On the other hand, the location and type of the termination of the fiber ends was very important. The FBG [4] fiber was terminated at a distance 1 m from the FBG with a flat cleave, and the other side of the FBG—the fibre was left at its manufactured length (0.5 m), and cleaved angled. The FBG [6] fibre was terminated right after the FBG (at approx. 1 mm), and cleaved flat; the other end was left at its manufactured length (0.5 m), and cleaved angled.

The tips of both fibers that were cleaved flat were used to couple the light into the fiber, and the other ends that were cleaved angled—for connecting to the measuring device, either power meter or optical spectrum analyzer.

For supporting the fibers, both ends were inserted into ferrules and then mounted on a special high-precision 3-dimensional stage with tilt adjustment.

The actual coupling of the light was performed in two parts.

First, the light from the front facet of the laser was coupled into the low-reflectivity FBG [4] fiber for receiving maximum power. After fine 3-D and tilt alignment, we were able to achieve 60% coupling efficiency, when the fiber was directly coupled with the front emitting surface of the laser, and placed very close to it (to a few μm) (FIG. 1).

Then, the light from the back facet of the laser was coupled into the high-reflectivity FBG [6] fiber for receiving maximum power. After fine 3-D and tilt alignment, we were able to achieve about 15% coupling efficiency with respect of the reflectivity of the FBG [6].

The locking and stabilizing of the emission wavelength of the laser was established by additional fine adjustment of the X,Y- and tilt-position of the front facet fiber, and simultaneously measuring of the output power and spectrum. Maintaining the same power level, the peak wavelength of the diode was “locked” and stabilized, and the bandwidth was reduced to about 10% of the original LD peak width.

### BRIEF DESCRIPTION OF THE DRAWINGS

For a better understanding of the present invention, reference is made to the following detailed description and the attached figures, where:

FIG. 1 represents the experimental setup, in which two fibers with FBGs written on them are coupled with the front and back emitting surfaces of a laser diode.

FIG. 2 shows the same setup, but in which the coupling of the light from laser diode is made by using two optical lenses.

FIG. 3 shows the same setup, but in which the coupling of the light from laser diode is made by terminating the two fibers ends with ball lenses.

FIG. 4 shows the same setup, but in which the fiber facing the front emitting surface of the laser diode has two FBGs written on it, located at distance D3, and the fiber facing the back emitting surface has a single FBG.

FIG. 5 shows the same setup, but in which the fiber facing the back emitting surface of the laser diode has two FBGs written on it, located at distance D4, and the fiber facing the front emitting surface has a single FBG.

FIG. 6 shows the same setup, but in which each of both fibers have two FBGs written on them, and located at distance D3 and D4 respectively.

### LEGEND TO THE DRAWINGS

With reference to the annexed drawing in FIG. 1 to FIG. 6, the following numbering is used:

1. Laser diode.

2. Front emitting facet of the laser diode.

3. Back emitting facet of the laser diode.

4. Fiber Bragg Grating written on the fiber facing the front emitting surface of the laser diode.

5. Fiber facing the front emitting surface of the laser diode and located at distance D1.

6. Fiber Bragg Grating written on the fiber facing the back emitting surface of the laser diode and located at distance D2.

7. Fiber facing the back emitting surface of the laser diode.

8. Optical lens facing the back emitting surface of the laser diode.

9. Optical lens facing the front emitting surface of the laser diode.

10. Ball lens termination of the fiber facing the back emitting surface of the laser diode.

11. Ball lens termination of the fiber facing the front emitting surface of the laser diode.

12. Second FBG written on the fiber facing the front emitting surface of the laser diode and located at distance D3.

13. Second FBG written on the fiber facing the back emitting surface of the laser diode and located at distance D4.

### REFERENCES

1. Grant Rogers, Brian F. Ventrudo, Fibre grating stabilized diode laser, U.S. Pat. No. 0,571,5263

2. Jean-Marc Verdiell, Robert J. Lang, Thomas L. Koch, Mehrdad Ziari. Waveguide DBR Light

Emitting Device, U.S. Pat. No. 5,870,417 A

3. Dmitri V. Kuksenkov, John D. Minelly, Luis A. Zenteno. Semiconductor or solid-state laser having an external fiber cavity, U.S. Pat. No. 6,625,182 B

4. Pin Long. Sliced Fiber Bragg Grating used as external cavity for semiconductor laser and solid state laser, U.S. Pat. No. 8,018,982 B2

5. Hong-Gang Yu, Chang-Qing Xu, Yong Wang, Jacek Wojcik, Zhi-Lin Peng and Peter Mascher. External-Cavity Semiconductor Laser with Bragg Grating in Multimode Fiber, IEEE PHOTONICS TECHNOLOGY LETTERS, VOL. 16, NO. 10, OCTOBER 2004

We claim:

1. An External Cavity Laser Diode (ECLD) is a system configuration, in which a laser diode is used as a light source, and in which an optical feedback is provided by two Fiber Bragg Gratings (FBGs) at the front and the back facet of the laser to create external cavity and to control the LD output characteristics (FIG. 1).

2. A device as defined in claim 1, where a laser diode is a single mode laser diode or multi mode laser diode.

3. A device as defined in claim 1, where a single mode or multimode fiber is coupled directly with laser diode front facet, and has a FBG written on it (FBG [4]).

4. A device as defined in claim 1, where another single mode or multimode fiber is coupled directly with laser diode back facet, and has a FBG written on it (FBG [6]) (FIG. 1).

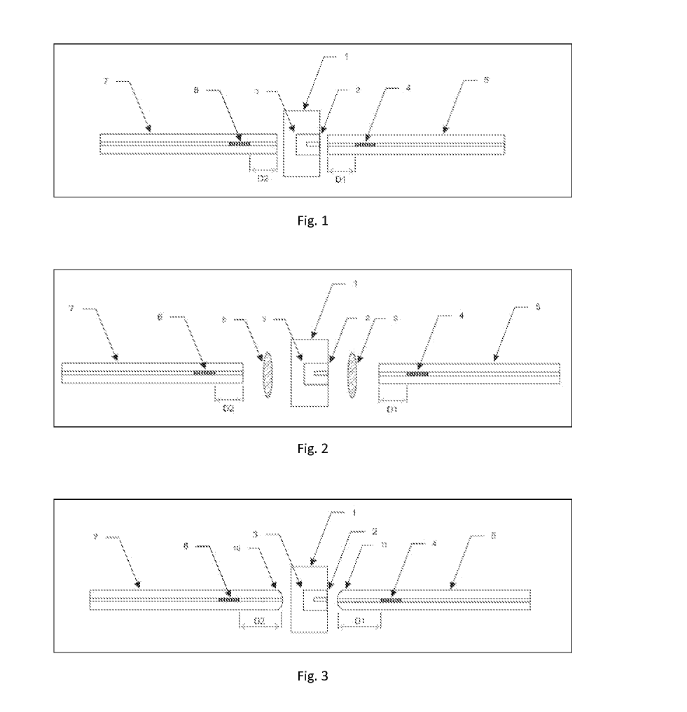

5. A device as defined in claim 1, where the both single mode or multi mode fibers are coupled to the laser using optical lenses [8, 9] (FIG. 2).

6. A device as defined in claim 1, where a lensed fiber [10] is used to couple the light into Fiber [5] with FBG [4], and another lensed fiber [11] is used to the light into Fiber [7] with FBG [6] (FIG. 3).

7. A device as defined in claim 1, where the central wavelength of the both FBGs are overlapping with the peak emission wavelength of the laser diode.

8. A device as defined in claim 1, where the FBG [4] has low reflectivity and the FBG [6] has high reflectivity.

9. A device as defined in claim 1, where the FBG [4] has high reflectivity and the FBG [6] has low reflectivity.

10. A device as defined in claim 1, where both FBG [4] and FBG [6] have low reflectivity.

11. A device as defined in claim 1, where both FBG [4] and FBG [6] have high reflectivity.

12. A device as defined in claim 1, where the bandwidth of FBG [4] is narrow and bandwidth of FBG [6] is wide.

13. A device as defined in claim 1, where the FBG [4] is far from the laser front emitting facet, and the FBG [6] is close to the laser back emitting facet.

14. A device as defined in claim 1, where the FBG [4] is close to the laser front emitting facet, and the FBG [6] is far from the laser back emitting facet.

15. A device as defined in claim 1, where both FBG [4] and FBG [6] are far from the laser.

16. A device as defined in claim 1, where both FBG [4] and FBG [6] are close the laser.

17. A device as defined in claim 1, where the front facet and back facet of laser diode are both coated with anti-reflection (AR) coating.

18. A device as defined in claim 1, where the front facet is coated with anti-reflection coating (AR), and the back facet is coated with high-reflection coating (HR).

19. A device as defined in claim 1, where the both front facet and the back facet of the laser diode are not coated.

20. A device as defined in claim 1, where the fibers' tips facing the laser diode are terminated with flat cleave, and the other ends are terminated with angled cleave.

21. A device as defined in claim 1, where the Fiber [5] facing the front emitting surface of the laser diode has second FBG [12] written on it, located at distance D3, and the Fiber [7] facing the back emitting surface has a single FBG [6] (FIG. 4).

22. A device as defined in claim 1, where the Fiber [7] facing the back emitting surface of the laser diode has second FBG [13] written on it, located at distance D4, and the Fiber [5] facing the front emitting surface has a single FBG [4] (FIG. 5).

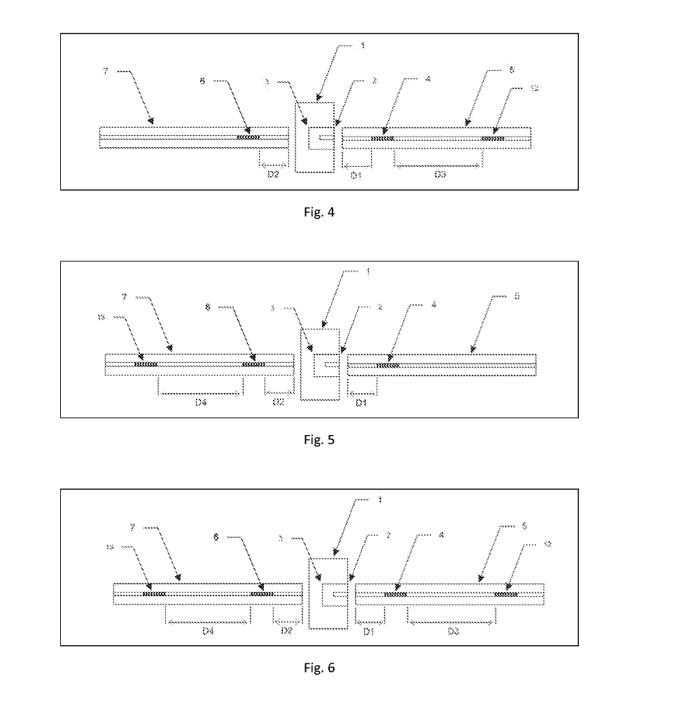

23. A device as defined in claim 1, where the fiber [5] has two FBGs [4] and [12], located at distance D3 and the fiber [7] has also two FBGs [6] and [13], located at distance D4 respectively (FIG. 6).

24. A device as defined in claim 1 can decrease significantly the bandwidth of the LD.

25. A device as defined in claim 1 can lock and stabilize the central wavelength of the LD.

26. A device as defined in claim 1 can improve significantly the power stability of the LD.
